(19) United States
(12) Patent Application Publication
(10) Pub. No.: US 2026/0255709 A1
(43) Pub. Date: Aug. 27, 2026

(54) INTEGRATED SENSOR PACKAGE STRUCTURE

(71) Applicant: TONG HSING ELECTRONIC INDUSTRIES, LTD., Taoyuan City (TW)

(72) Inventors: JUI-HUNG HSU, Taoyuan City (TW); CHIEN-CHEN LEE, Taoyuan City (TW); CHIEN-HENG LIN, Taoyuan City (TW)

(21) Appl. No.: 19/245,377

(22) Filed: Jun. 22, 2025

(30) Foreign Application Priority Data
Feb. 27, 2025 (TW) 114107235

(51) Int. Cl. H10F 39/00

(52) U.S. Cl. CPC H10F 39/804; H10F 39/8063; H10F 39/811

(57) ABSTRACT

An integrated sensor package structure. The integrated sensor package structure includes a substrate, a plurality of sensor package units, and an encapsulation layer. The substrate has a first surface and a second surface. The sensor package units are disposed on the first surface. Each of the sensor package units includes a sensor chip disposed on the first surface, a light-permeable member arranged above the sensor chip, and an optical module disposed on a surface of the light-permeable member. The optical module includes a frame disposed on the sensor chip and a lens mounted in the frame. The encapsulation layer surrounds an outer periphery of each of the sensor units. A thickness of the sensor chip of at least one of the sensor package units is different from a thickness of the sensor chip of another one of the sensor package units.

### CROSS-REFERENCE TO RELATED PATENT APPLICATION

This application claims the benefit of priority to Taiwan Patent Application No. 114107235, filed on Feb. 27, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a sensor package structure, and more particularly to an integrated sensor package structure.

### BACKGROUND OF THE DISCLOSURE

Generally, in a conventional sensor package structure, a plurality of different sensor package units are usually individually packaged, and then the different sensor package units that are packaged are combined. However, this way of packaging causes the conventional sensor package structure to have a problem of insufficient structural simplicity.

### SUMMARY OF THE DISCLOSURE

In response to the above-referenced technical inadequacy, the present disclosure provides an integrated sensor package structure, so as to mainly improve on a problem of insufficient structural simplicity of a conventional sensor package structure.

In order to solve the above-mentioned problems, one of the technical aspects adopted by the present disclosure is to provide an integrated sensor package structure. The integrated sensor package structure includes a substrate, a plurality of sensor package units, and an encapsulation layer. The substrate has a first surface and a second surface opposite to each other. The sensor package units are disposed on the substrate. Each of the sensor package units includes a sensor chip disposed on the first surface, a light-permeable member disposed above the sensor chip, and an optical module disposed on a surface of the light-permeable member away from the sensor chip. The optical module includes a frame disposed on the sensor chip and at least one lens mounted in the frame. The encapsulation layer surrounds an outer periphery of the sensor chip and an outer periphery of the light-permeable member of each of the sensor package units. A thickness of the sensor chip of at least one of the sensor package units is different from a thickness of the sensor chip of another one of the sensor package units. A thickness of the light-permeable member of at least one of the sensor package units is different from a thickness of the light-permeable member of another one of the sensor package units.

In order to solve the above-mentioned problems, another one of the technical aspects adopted by the present disclosure is to provide an integrated sensor package structure. The integrated sensor package structure includes a substrate, a plurality of sensor package units, and an encapsulation layer. The substrate has a first surface and a second surface opposite to each other. The sensor package units are disposed on the first surface. Each of the sensor package units includes a sensor chip disposed on the first surface, a light-permeable member disposed above the sensor chip, and an optical module disposed on a surface of the light-permeable member away from the sensor chip. The optical module includes a frame disposed on the sensor chip and at least one lens mounted in the frame. The encapsulation layer surrounds an outer periphery of the sensor chip and an outer periphery of the light-permeable member of each of the sensor package units. A thickness of the sensor chip of at least one of the sensor package units is different from a thickness of the sensor chip of another one of the sensor package units.

Therefore, in the integrated sensor package structure, by virtue of “the sensor package units being disposed on the first surface of the substrate” and “a thickness of the sensor chip of at least one of the sensor package units being different from a thickness of the sensor chip of another one of the sensor package units,” the problem of insufficient structural simplicity of the conventional sensor package structure can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of an integrated sensor package structure according to a first embodiment of the present disclosure;

FIG. 2 is a schematic exploded view of the integrated sensor package structure according to the first embodiment of the present disclosure;

FIG. 3 is a schematic cross-sectional view along line III-III in FIG. 1;

FIG. 4 is a schematic view showing that an encapsulation layer of the integrated package structure is made of a liquid encapsulation glue according to the first embodiment of the present disclosure;

FIG. 5 is a schematic perspective view of an integrated sensor package structure according to a second embodiment of the present disclosure; and

FIG. 6 is a schematic enlarged view of area VI in FIG. 5.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

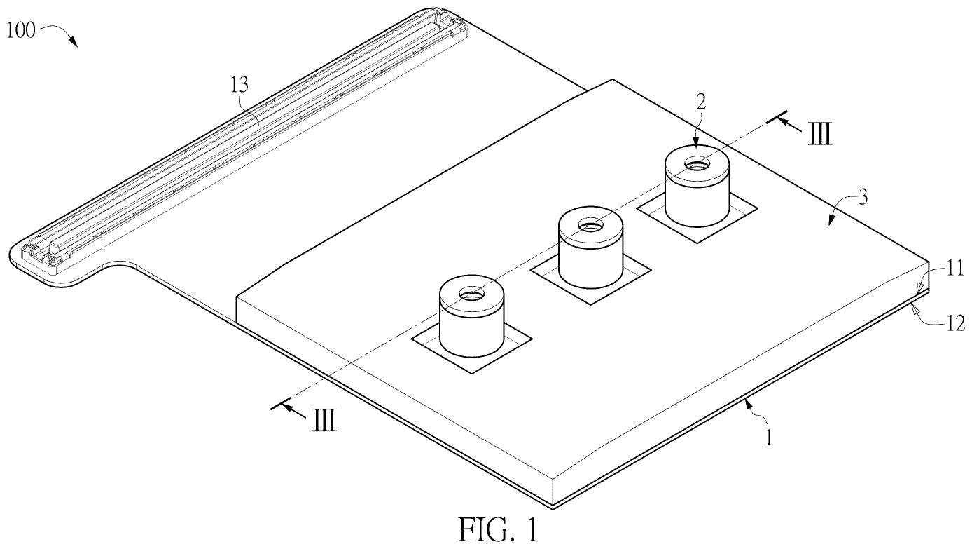

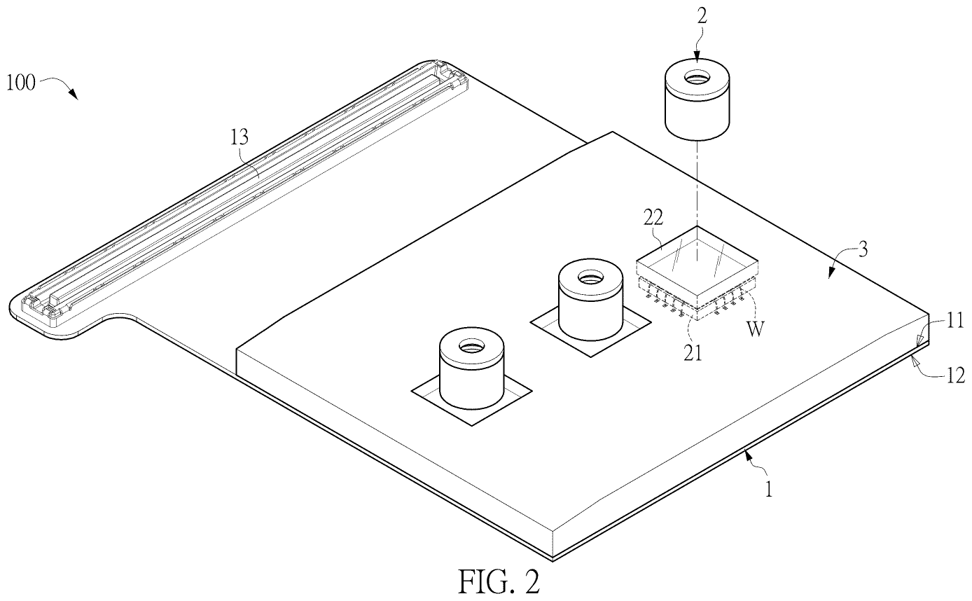

Referring to FIG. 1 and FIG. 2, FIG. 1 is a schematic perspective view of an integrated sensor package structure according to a first embodiment of the present disclosure, and FIG. 2 is a schematic exploded view of the integrated sensor package structure according to the first embodiment of the present disclosure. A first embodiment of the present disclosure provides an integrated sensor package structure 100. The integrated sensor package structure 100 includes a substrate 1, a plurality of sensor package units 2, and an encapsulation layer 3. The substrate 1 has a first substrate 11 and a second substrate 12 opposite to each other. The substrate 1 can be, for example, a ceramic board or a printed circuit board.

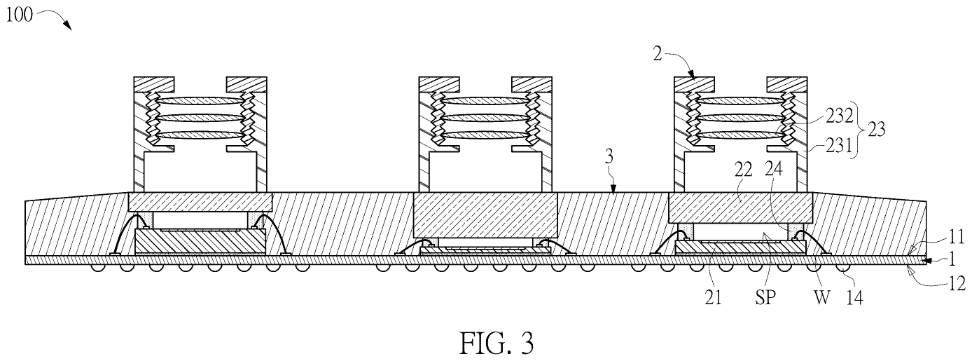

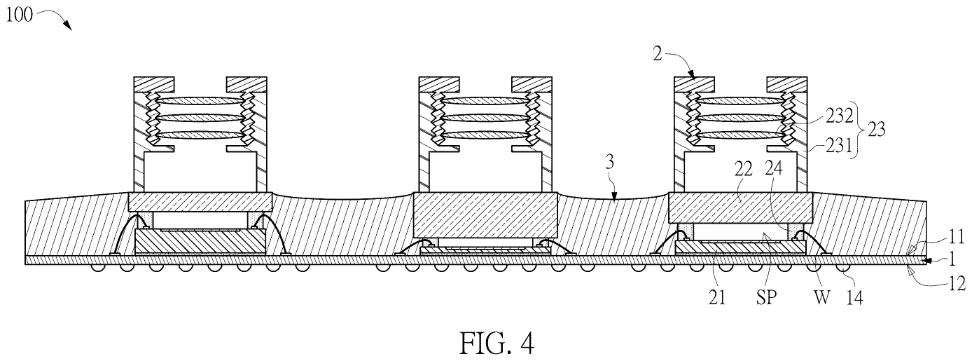

Referring to FIG. 3 and FIG. 4, FIG. 3 is a schematic cross-sectional view along line III-III in FIG. 1, and FIG. 4 is a schematic view showing that an encapsulation layer of the integrated package structure is made of a liquid encapsulation glue according to the first embodiment of the present disclosure. The sensor package units 2 are disposed on the first surface 11 of the substrate 1. Each of the sensor package units 2 can be, for example, a ball grid array (i.e., BGA). Each of the sensor package units 2 includes a sensor chip 21, a light-permeable member 22, and an optical module 23.

In addition, each of the sensor package units 2 can further include a plurality of wires W. One end of each of the wires W is connected to the first surface 11 of the substrate 1, and another end of each of the wires W is connected to the sensor chip 21. The encapsulation layer 3 surrounds an outer periphery of the sensor chip 21 of each of the sensor package units 2 and surrounds an outer periphery of the light-permeable member 22 of each of the sensor package units 2. Preferably, as shown in FIG. 4, the encapsulation layer 3 can be made of a liquid encapsulation glue, but the present disclosure is not limited thereto.

The substrate 1 can further include an electrical connector 13 (as shown in FIG. 1 and FIG. 2) disposed thereon, the substrate 1 can include a plurality of solder balls 14 formed on the second surface 12, and the solder balls 14 can be soldered on an electrical component (not shown), such that the sensor package units 2 can be electrically connected to the electrical component. In addition, in the present embodiment, a quantity of the sensor package units 2 is three, but the present disclosure is not limited thereto. For example, in other embodiments, the quantity of the sensor package units 2 can be two or more than three.

In each of the sensor package units 2, the sensor chip 21 is disposed on the first surface 11 of the substrate 1. The sensor chip 21 can be an image sensing chip, and the light-permeable member 22 can be a transparent glass, but the present disclosure is not limited thereto. The light-permeable member 22 is disposed above the sensing chip 21, and the optical module 23 is disposed on a surface of the light-permeable member 22 away from the sensor chip 21.

A thickness of the sensor chip 21 of at least one of the sensor package units 2 is different from a thickness of the sensor chip 21 of another one of the sensor package units 2. In the present embodiment, the sensor chip 21 of each of the sensor package units 2 has a different thickness, but the present disclosure is not limited thereto.

In other words, in the integrated sensor package structure 100, different sensor package units 2 are integrated on the substrate 1, so as to achieve simplifying an overall structure, and the sensor package units 2 include the sensor chips having different thicknesses, such that the integrated sensor package structure 100 can adapt to different focusing distances.

In the integrated sensor package structure 100 of the present embodiment, a thickness of the light-permeable member 22 of at least one of the sensor package units 2 is different from a thickness of the light-permeable member 22 of another one of the sensor package units 2. In the present embodiment, the light-permeable member 22 of each of the sensor package units 2 has a different thickness, but the present disclosure is not limited thereto.

In addition, in each of the sensor package units 2 of the present embodiment, the thickness of the sensor chip 21 is in an inverse relationship with the thickness of the light-permeable member 22, but the present disclosure is not limited thereto. In other words, in each of the sensor package units 2, the greater the thickness of the sensor chip 21 is, the smaller the thickness of the light-permeable member 22 is. Preferably, in each of the sensor package units 2, a sum of the thickness of the sensor chip 21 and the thickness of the light-permeable member 22 is less than 2 mm, but the present disclosure is not limited thereto.

In addition, in each of the sensor package units 2, a supporting glue layer 24 is formed between the sensor chip 21 and the light-permeable member 22. The supporting glue layer 24 is in an annular shape and arranged between the sensor chip 21 and the light-permeable member 22, and the supporting glue layer 24, the sensor chip 21, and the light-permeable member 22 can jointly define an enclosed space SP. In addition, one end of each of the wires W can be connected to the sensor chip 21 and arranged in the supporting glue layer 24, but the present disclosure is not limited thereto. In other embodiments, one end of each of the wires W can be not arranged in the supporting glue layer 24, but the present disclosure is not limited thereto.

The optical module 23 of each of the sensor package units 2 includes a frame 231 disposed on the sensor chip 21 and at least one lens 232 mounted in the frame 231. It is worth mentioning that, the optical module 23 can be directly disposed on the surface of the light-permeable member 22 away from the sensor chip 21 through a bottom edge of the frame 231. In other words, any other optical module that is not directly disposed on a sensor chip is not suitable to be compared to the optical module 23 of the present embodiment. In addition, a projection area formed by orthographically projecting the optical module 23 of each of the sensor package units 2 is only located on the surface of the sensor chip 21, but the present disclosure is not limited thereto.

In addition, in the present embodiment, the optical module 23 of each of the sensor package units 2 includes three lenses 232, but the present disclosure is not limited thereto. In other embodiments, the quantity of the lens 232 included by the optical module 23 of each of the sensor package units 2 can be one or more.

In the present embodiment, the optical module 23 included by each of the sensor package units 2 can have a substantially same height, but the present disclosure is not limited thereto. In other embodiments, the optical module 23 included by each of the sensor package units 2 can have a different height, but the present disclosure is not limited thereto.

### Second Embodiment

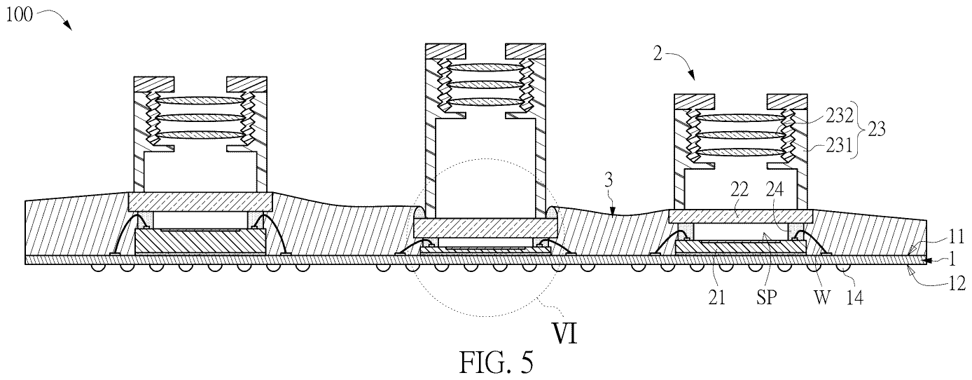

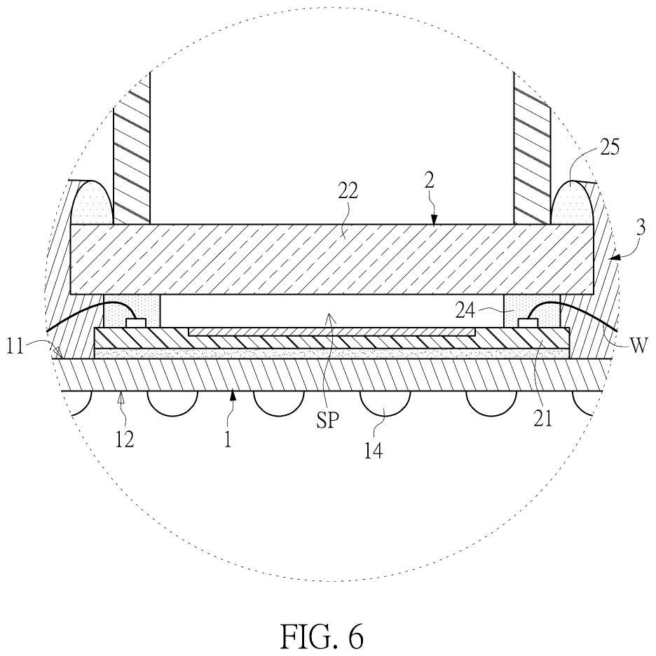

Referring to FIG. 5 and FIG. 6, FIG. 5 is a schematic perspective view of an integrated sensor package structure according to a second embodiment of the present disclosure, and FIG. 6 is a schematic enlarged view of area VI in FIG. 5. The second embodiment of the present disclosure is similar to the first embodiment of the present disclosure, the similar parts of the two embodiments will not be reiterated herein, and the different parts between the two embodiments are described as follows.

In each of the sensor package units 2 of the present embodiments, the thickness of the sensor chip 21 can be not in an inverse relationship with the thickness of the light-permeable member 22, and the light-permeable member 22 of each of the sensor package units 2 can have a substantially same height.

In addition, in each of the sensor package units 2 of the present embodiment, the thickness of the sensor chip 21 can be in a positive relationship with a distance between the light-permeable member 22 and the substrate 1, but the present disclosure is limited thereto. In other words, in each of the sensor package units 2, the greater the thickness of the sensor chip 21 is, the greater the distance between the light-permeable 22 and the substrate 1 is.

In the present embodiment, at least one of the sensor package units 2 includes an annular retaining wall 25, the annular retaining wall 25 is formed at the surface of the light-permeable member 22 away from the sensor chip 21, and a distance between the light-permeable member 22 of the at least one of the sensor package units 2 and the substrate 1 is less than a distance between the light-permeable member 22 of another one of the sensor package units 2 and the substrate 1. The annular retaining wall 25 can surround one end of the optical module 23 adjacent to the sensor chip 21. The annular retaining wall 25 can be made of a curing glue, but the present disclosure is not limited thereto. In addition, a ratio between a height of the retaining wall 25 and the thickness of the light-permeable member 22 can be between ½ and ⅓, or the height of the annular wall 25 can be between 100 μm and 300 μm, but the present disclosure is not limited thereto.

It is worth mentioning that, since the distance between the sensor chip 21 of each of the sensor package units and the substrate 1 can be different, it can be ensured that the liquid encapsulation glue does not flood onto the surface of the light-permeable member 22 through the annular retaining wall 25 formed on the surface of the light-permeable member 22 that has a smaller distance between the substrate 1.

It is worth mentioning that, in the first embodiment, the distance between the light-permeable member 22 and the substrate 1 of any one of the sensor package units 2 can be substantially the same as the distance between the light-permeable member 22 of another one of the sensor package units 2 and the substrate 1. In other words, the light-permeable member 22 of each of the sensor package units 2 can be disposed at a same horizontal height, and the surface of the light-permeable member 22 of each of the sensor package units 2 can be provided without the annular retaining wall 25 formed thereon.

In addition, in the present embodiment, a height of the optical module 23 (e.g., a distance between one end of the optical module 23 away from the sensor chip 21 and the sensor chip 21) can be changed according to the thickness of the sensor chip 21 or according to practical requirements, but the present disclosure is not limited thereto.

In the present embodiment, the height of the optical module 23 of any one of the sensor package units 2 is different from the height of the optical module 23 of another one of the sensor package units 2, but the present disclosure is not limited thereto. In other embodiments, the optical module 23 of each of the sensor package units 2 can have a substantially same height. In addition, a dimension of the optical module 23 along a horizontal direction can be changed according to practical requirements, and the optical module 23 of each of the sensor package units 2 can have a substantially same dimension or a different dimension along the horizontal direction.

### Beneficial Effects of the Embodiments

In conclusion, in the integrated sensor package structure, by virtue of “the sensor package units being disposed on the first surface of the substrate” and “a thickness of the sensor chip of at least one of the sensor package units being different from a thickness of the sensor chip of another one of the sensor package units,” the problem of insufficient structural simplicity of the conventional sensor package structure can be improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An integrated sensor package structure, comprising:
a substrate having a first surface and a second surface opposite to each other;
a plurality of sensor package units disposed on the substrate; wherein each of the sensor package units includes:
a sensor chip disposed on the first surface;
a light-permeable member disposed above the sensor chip; and
an optical module disposed on a surface of the light-permeable member away from the sensor chip; wherein the optical module includes:
a frame disposed on the sensor chip; and
at least one lens mounted in the frame; and
an encapsulation layer surrounding an outer periphery of the sensor chip and an outer periphery of the light-permeable member of each of the sensor package units;
wherein a thickness of the sensor chip of at least one of the sensor package units is different from a thickness of the sensor chip of another one of the sensor package units, and
wherein a thickness of the light-permeable member of at least one of the sensor package units is different from a thickness of the light-permeable member of another one of the sensor package units.

2. The integrated sensor package structure according to claim 1, wherein the encapsulation layer is made of a liquid encapsulation glue.

3. The integrated sensor package structure according to claim 1, wherein, in each of the sensor package units, the thickness of the sensor chip is in an inverse relationship with the thickness of the light-permeable member.

4. The integrated sensor package structure according to claim 3, wherein, in each of the sensor package units, a sum of the thickness of the sensor chip and the thickness of the light-permeable member is less than 2 mm.

5. The integrated sensor package structure according to claim 1, wherein a distance between the light-permeable member of any one of the sensor package units and the substrate is the same as a distance between the light-permeable member of another one of the sensor package units and the substrate.

6. The integrated sensor package structure according to claim 1, wherein each of the sensor package units includes a support glue layer, the support glue layer is in an annular shape and is arranged between the sensor chip and the light-permeable member, and the support glue layer, the sensor chip, and the light-permeable member jointly define an enclosed space.

7. The integrated sensor package structure according to claim 6, wherein each of the sensor package units includes a plurality of wires, and each of the wires has one end connected to the first surface and has another end connected to the sensor chip and disposed in the support glue layer.

8. An integrated sensor package structure, comprising
a substrate having a first surface and a second surface opposite to each other;
a plurality of sensor package units disposed on the first surface, wherein each of the sensor package units includes:
a sensor chip disposed on the first surface;
a light-permeable member disposed above the sensor chip; and
an optical module disposed on a surface of the light-permeable member away from the sensor chip, wherein the optical module includes:
a frame disposed on the sensor chip; and
at least one lens mounted in the frame; and
an encapsulation layer surrounding an outer periphery of the sensor chip and an outer periphery of the light-permeable member of each of the sensor package units;
wherein a thickness of the sensor chip of at least one of the sensor package units is different from a thickness of the sensor chip of another one of the sensor package units.

9. The integrated sensor package structure according to claim 8, wherein the encapsulation layer is made of a liquid encapsulation glue.

10. The integrated sensor package structure according to claim 8, wherein, in each of the sensor package units, a thickness of the sensor chip is in a positive relationship with a distance between the light-permeable member and the substrate.

11. The integrated sensor package structure according to claim 8, wherein at least one of the sensor package units includes an annular retaining wall, and the annular retaining wall is formed at a surface of the light-permeable member away from the sensor chip.

12. The integrated sensor package structure according to claim 11, wherein a distance between the light-permeable member of the at least one of the sensor package units and the substrate is less than a distance between the light-permeable member of another one of the sensor package units and the substrate.

13. The integrated sensor package structure according to claim 8, wherein each of the sensor package units includes a support glue layer, the support glue layer is in an annular shape and arranged between the sensor chip and the light-permeable member, and the support glue layer, the sensor chip, and the light-permeable member jointly define an enclosed space.

14. The integrated sensor package structure according to claim 13, wherein each of the sensor package units includes a plurality of wires, and each of the wires has one end connected to the first surface and has another end connected to the sensor chip and disposed in the support glue layer.
